(19) United States
(12) Patent Application Publication
(10) Pub. No.: US 2018/0090197 A1
(43) Pub. Date: Mar. 29, 2018

(54) SEMICONDUCTOR DEVICE

(71) Applicant: Renesas Electronics Corporation, Tokyo (JP)

(72) Inventor: Takayuki HOTARUHARA, Tokyo (JP)

(21) Appl. No.: 15/656,876

(22) Filed: Jul. 21, 2017

(30) Foreign Application Priority Data
Sep. 28, 2016 (JP) 2016-189440

(51) Int. Cl. G11C 11/4093; G11C 11/4076

(52) U.S. Cl. CPC G11C 11/4093; G11C 11/4076

(57) ABSTRACT

A data signal may not be fetched by using a data strobe signal if the waveform of the data is degraded with an increase in speed. In order to solve this problem, a first selection unit generates a first selection signal that indicates which one of a plurality of lanes Lane0 and Lane1 for transmitting a data signal that is input at a double data rate from the outside, based on a first strobe signal that is input from the outside. A gate unit sorts the data signal into any of the lanes Lane0 and Lane1 to output data signals Data1_0 and Data1_1, based on the first selection signal. Then, a latch unit latches the data signals Data1_0 and Data1_1 output to the lanes and outputs data signals Data2_0 and Data2_1.

### CROSS-REFERENCE TO RELATED APPLICATIONS

The disclosure of Japanese Patent Application No. 2016-189440 filed on Sep. 28, 2016 including the specification, drawings and abstract is incorporated herein by reference in its entirety.

### BACKGROUND

The present invention relates to a semiconductor device, and specifically, for example, to a semiconductor device including a memory interface.

DDR data receiving circuits have been known to perform a read or write on a double data rate (DDR) memory device (see, for example, Patent Document 1 (Japanese Unexamined Patent Application Publication (Translation of PCT Application) No. 2006-505866)). In the DDR data receiving circuit, the data is fetched by using a strobe signal.

### SUMMARY

In a DDR data receiving circuit such as that described in Patent Document 1, a data signal may not be fetched by using a strobe signal if the waveform of the data is degraded with an increase in speed.

These and other objects and novel features of the present invention will become more apparent from the following detailed description, taken in conjunction with the accompanying drawings.

A semiconductor device according to an embodiment selects any one of a plurality of lanes for transmitting a data signal that is input at a double data rate from the outside based on a strobe signal input from the outside, sorts the data signal into any of the lanes to output data signals based on the selection, and latches the data signals output to the lanes.

According to an embodiment, it is possible to reliably fetch the data signal even if the waveform of the data is degraded.

### BRIEF DESCRIPTION OF THE DRAWINGS

FIG. 1 is a diagram showing the configuration of a semiconductor device according to a first embodiment;

FIG. 2 is a diagram showing the configuration of a sample circuit according to a comparative example;

FIG. 3 is a timing diagram of the signals (data) within the sample circuit, the signals (data) input to the sample circuit, and the signals (data) output from the sample circuit according to the comparative example;

FIG. 4 is a diagram showing the configuration of a semiconductor device according to a second embodiment;

FIG. 5 is a diagram showing the configuration of a sample circuit according to the second embodiment;

FIG. 6 is a diagram showing the configuration of a gate unit according to the second embodiment;

FIG. 7 is a diagram showing the configuration of a latch unit according to the second embodiment;

FIG. 8 is a timing diagram of the signals (data) within the sample circuit, the signals (data) input to the sample circuit, and the signals (data) output from the sample circuit according to the second embodiment;

FIG. 9 is a diagram showing the configuration of a sample circuit according to a third embodiment;

FIG. 10 is a diagram showing the configuration of a gate unit according to the third embodiment;

FIG. 11 is a diagram showing the configuration of a latch unit according to the third embodiment;

FIG. 12 is a timing diagram of the signals (data) within the sample circuit, the signals (data) input to the sample circuit, and the signals (data) output from the sample circuit according to the third embodiment;

FIG. 13 is a diagram showing the configuration of a sample circuit according to a fourth embodiment; and

FIG. 14 is a timing diagram of the signals (data) within the sample circuit, the signals (data) input to the sample circuit, and the signals (data) output from the sample circuit according to the fourth embodiment;

### DETAILED DESCRIPTION

Hereinafter, embodiments of the present invention will be described with reference to the accompanying drawings.

### First Embodiment

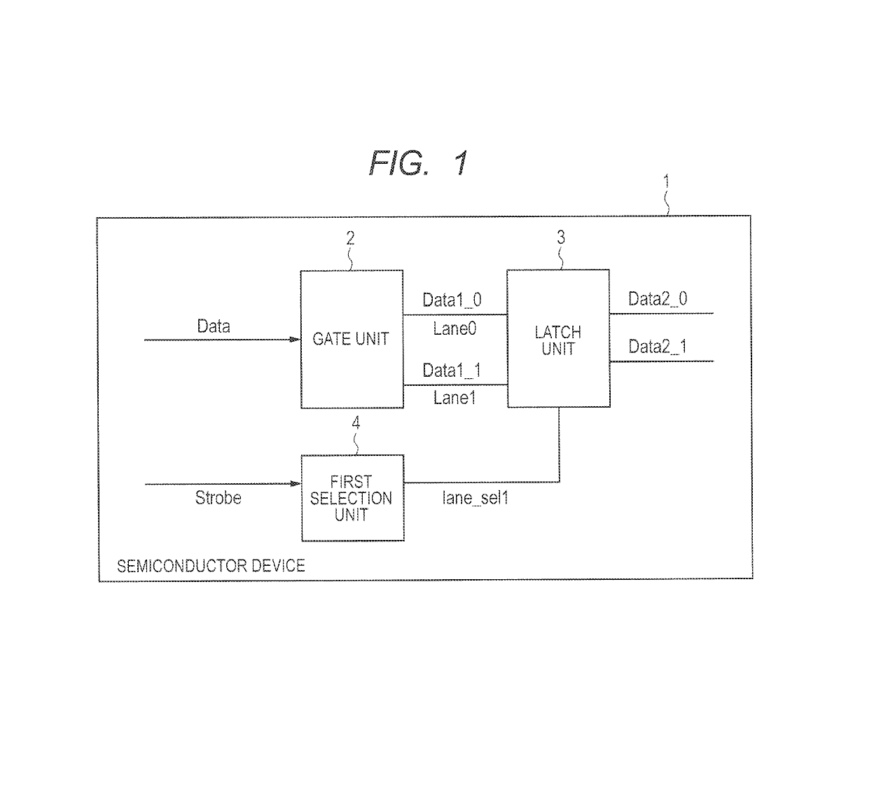

FIG. 1 is a diagram showing the configuration of a semiconductor device 1 according to a first embodiment.

The semiconductor device 1 is a semiconductor device that transmits a data signal input from the outside at a double data rate. The semiconductor device 1 includes a gate unit 2, a first selection unit 4, and a latch unit 3.

The first selection unit 4 generates a first selection signal lane_sel1 that indicates which lane is selected from a plurality of lanes Lane0 and Lane1 for transmitting a data signal Data that is input from the outside at a double data rate, based on a first strobe signal Strobe1 input from the outside.

The gate unit 2 sorts the data signal Data into any of the lanes to output data signals based on the first selection signal lane_sel1.

The latch unit 3 latches data signals Data1_0 and Data1_1 based on the first selection signal lane_sel1, and outputs data signals Data2_0 and Data2_1.

As described above, according to the present embodiment, the data signal Data is latched by the latch unit 3, so that it is possible to reliably fetch and transmit the data signal Data even if the timing of the arrival of the data signal Data largely deviates from the first strobe signal Strobe1.

### Comparative Example

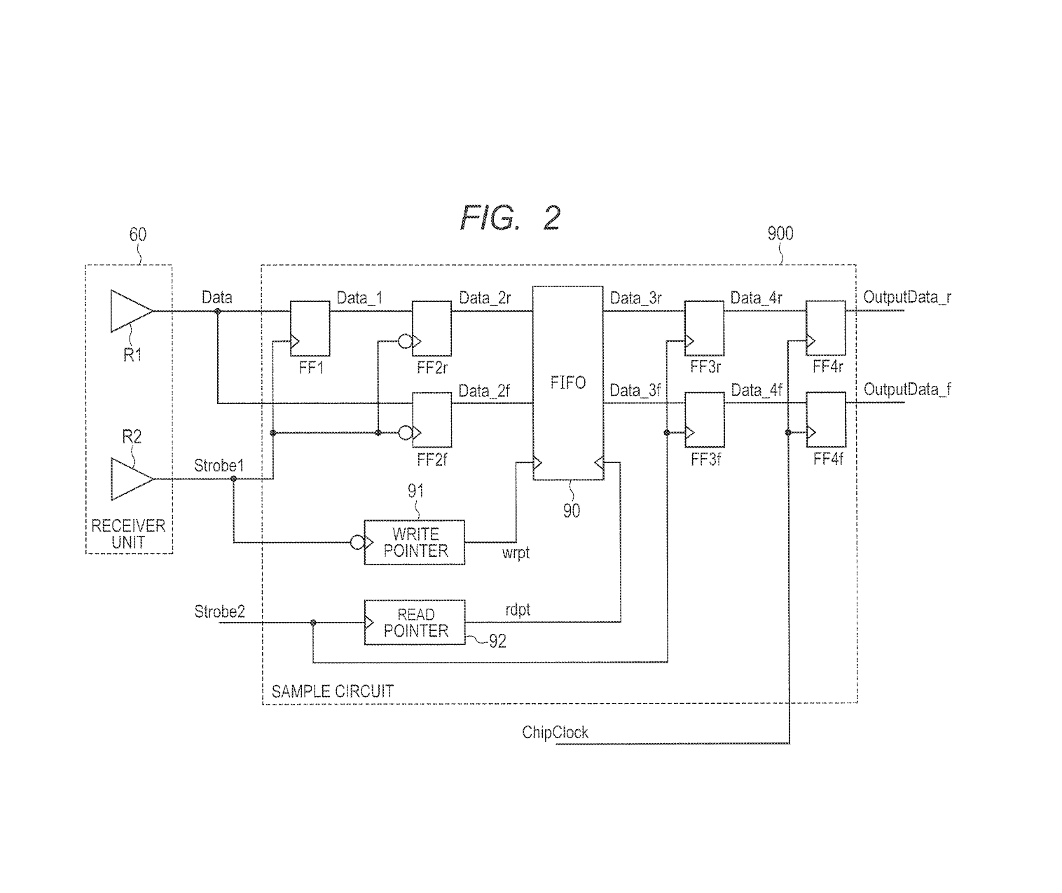

FIG. 2 is a diagram showing the configuration of a sample circuit 900 according to a comparative example.

The sample circuit 900 includes a flip-flop FF1, flip-flops FF2r and FF2f, a FIFO 90, a write pointer supply unit 91, a read pointer supply unit 92, flip-flops FF3r and FF3f, and flip-flops FF4r and FF4f.

The flip-flop FF1 fetches a data signal Data that is input at a double data rate from a receiver R1 in the timing of occurrence of the rising edge of the external strobe signal Strobe1 that is output from a receiver R2. Then, the flip-flop FF1 holds the data signal Data and outputs as a data signal Data_1.

The flip-flop FF2r fetches the data signal Data_1 in the timing of occurrence of the falling edge of the external strobe signal Strobe1. Then, the flip-flop FF2r holds the data signal Data_1 and outputs as a data signal Data_2r. The flip-flop FF2f fetches the data signal Data in the timing of occurrence of the falling edge of the external strobe signal Strobe1. Then, the flip-flop FF2f holds the data signal Data and outputs as a data signal Data_2f.

The write pointer supply unit 91 updates the value of a write pointer wrpt in the timing of occurrence of the falling edge of the external strobe signal Strobe1. The FIFO 90 writes the data signals Data_2r and Data_2f in the position indicated by the write pointer wrpt.

The read pointer supply unit 92 updates the value of a read pointer rdpt in the timing of occurrence of the rising edge of an internal strobe signal Strobe2. The FIFO90 outputs the data stored in the position indicated by the read pointer rdpt, as data signals Data_3r and Data_3f.

The flip-flop FF3r fetches the data signal Data_3r in the timing of occurrence of the rising edge of the internal strobe signal Strobe2. Then, the flip-flop FF3r holds the data signal Data_3r and outputs as a data signal Data_4r. The flip-flop FF3f fetches the data signal Data_3f in the timing of occurrence of the rising edge of the internal strobe signal Strobe2. Then, the flip-flop FF3f holds the data signal Data_3f and outputs as a Data_4f.

The flip-flop FF4r fetches the data signal Data_4r in the timing of occurrence of the rising edge of a chip clock signal ChipClock. Then, the flip-flop FF4r holds the data signal Data_4r and outputs as a data signal OutputData_r. The flip-flop FF4f fetches the data signal Data_4f in the timing of occurrence of the rising edge of the chip clock signal ChipClock. Then, the flip-flop FF4f holds the data signal Data_4f and outputs as a data signal OutputData_f.

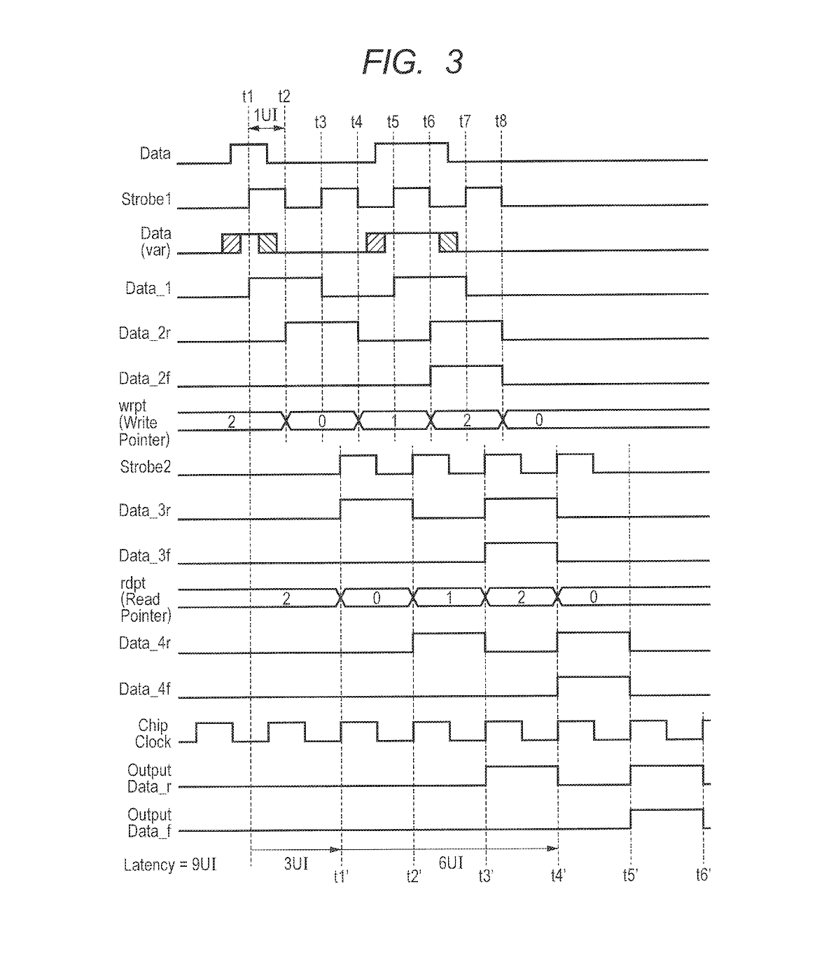

FIG. 3 is a timing diagram of the internal signals (data) of the sample circuit 900, the signals (data) input to the sample circuit 900, and the signals (data) output from the sample circuit 900 according to the comparative example.

In FIG. 3, Data (var) is a waveform taking into account the degradation of the data signal Data (shadow area). In FIG. 3, the shadow area is a data valid window, in which it is assumed that the signal rises in any one of the diagonal lines rising from left to right, and that the signal falls in any one of the diagonal lines rising from right to left. The width of the data signal Data is 1 UI (Unit Interval).

The input data signal Data, the external strobe signal Strobe1, the internal strobe signal Strobe2, and the chip clock signal ChipClock vary at every 1 UI (Unit Interval). The timings of the input data signal Data, the external strobe signal Strobe1, and the internal strobe signal Strobe2 are not synchronized with each other. The internal strobe signal Strobe2 is substantially synchronized with the chip clock signal ChipClock. The sequence of the input data signal Data is “10001100”.

When the external strobe signal Strobe1 rises at time t1, an input data signal Data (=1) is fetched by the flip-flop FF1. Then, an output data signal Data_1 of the slip-flop FF1 is changed to “1”.

When the external strobe signal Strobe1 falls at time t2, the Data_1 (=1) is fetched by the flip-flop FF2r, and an output data signal Data_2r is changed to “1”. At the same time, the output data signal Data (=0) is fetched by the flip-flop FF2f and an output data signal Data_2f is changed to “0”. Further, when the external strobe signal Strobe1 falls, the write pointer supply unit 91 updates the value of the write pointer wrpt to “0”. The FIFO 90 writes the data signals Data_2r (=1) and Data_2f (=0) in the position indicated by the write pointer wrpt (=0).

When the external strobe signal Strobe1 rises at time t3, the input data signal Data (=0) is fetched by the flip-flop FF1. Then, the output data signal Data_1 of the flip-flop FF1 is changed to “0”.

When the external strobe signal Strobe1 falls at time t4, the Data_1 (=0) is fetched by the flip-flop FF2r, and the output data signal Data_2r is changed to “0”. At the same time, the Data (=0) is fetched by the flip-flop FF2f, and the output data signal Data_2f is changed to “0”. Further, when the external strobe signal Strobe1 falls, the write pointer supply unit 91 updates the value of the write pointer wrpt to “1”. The FIFO 90 writes the data signals Data_2r (=0) and Data_2f (=0) in the position indicated by the write pointer wrpt (=1).

When the external strobe signal Strobe1 rises at time t5, the input data signal Data (=1) is fetched by the flip-flop FF1. Then, the output data signal Data_1 of the flip-flop FF1 is changed to “1”.

When the external strobe signal Strobe1 falls at time t6, the Data_1 (=1) is fetched by the flip-flop FF2r, and the output data signal Data_2r is changed to “1”. At the same time, the Data (=1) is fetched by the flip-flop FF2f, and the output data signal Data_2f is changed to “1”. Further, when the external strobe signal Strobe1 falls, the write pointer supply unit 91 updates the value of the write point wrpt to “2”. The FIFO 90 writes the data signals Data_2r (=1) and Data_2f (=1) in the position indicated by the write pointer wrpt (=2).

When the external strobe signal Strobe1 rises at time t7, the input data signal Data (=0) is fetched by the flip-flop FF1. Then, the output data signal Data_1 of the flip-flop FF1 is changed to “0”.

When the external strobe signal Strobe1 falls at time t8, the Data_1 (=0) is fetched by the flip-flop FF2r, and the output data signal Data_2r is changed to “0”. At the same time, the Data (=0) is fetched by the flip-flop FF2f, and the output data signal Data_2f is changed to “0”. Further, when the external strobe signal Strobe1 falls, the write pointer supply unit 91 updates the value of the write pointer wrpt to “0”. The FIFO 90 writes the data signals Data_2r (=0) and Data_2f (=0) in the position indicated by the write pointer wrpt (=0).

When the internal strobe signal Strobe2 rises at time t1′, the read pointer supply unit 92 updates the value of the read pointer rdpt to “0”. The FIFO 90 outputs the data signals Data_3r (=1) and Data_3f (=0) from the position indicated by the read pointer rdpt (=0).

When the chip clock signal ChipClock rises at time t2′, Data_4r (=0) is fetched by the flip-flop FF4r, and an output data signal OutputData_r of the flip-flop FF4r is changed to “0”. At the same time, the Data_4f (=0) is fetched by the flip-flop FF4f, and an output data signal OutputData_f of the flip-flop FF4f is changed to “0”. Further, when the internal strobe signal Strobe2 rises, the Data_3r (=1) is fetched by the flip-flop FF3r, and the output data signal Data_4r of the flip-flop FF3r is changed to “1”. At the same time, the Data_3f (=0) is fetched by the flip-flop FF3f, and the output data signal Data_4f of the flip-flop FF3f is changed to “0”. When the internal strobe signal Strobe2 rises, the read pointer supply unit 92 updates the value of the read pointer rdpt to “1”. The FIFO 90 outputs the data signals Data_3r (=0) and Data_3f (=0) from the position indicated by the read pointer rdpt (=1).

When the chip clock signal ChipClock rises at time t3′, the Data_4r (=1) is fetched by the flip-flop FF4r, and the output data signal OutputData_r of the flip-flop FF4r is changed to “1”. At the same time, the Data_4f (=0) is fetched by the flip-flop FF4f, and the output data signal OutputData_f of the flip-flop FF4f is changed to “0”. Further, when the internal strobe signal Strobe2 rises, the Data_3r (=0) is fetched by the flip-flop FF3r, and the output data signal Data_4r of the flip-flop FF3r is changed to “0”. At the same time, the Data_3f (=0) is fetched by the flip-flop FF3f, and the output data signal Data_4f of the flip-flop FF3f is changed to “0”. When the internal strobe signal Strobe2 rises, the read pointer supply unit 92 updates the value of the read pointer rdpt to “2”. The FIFO 90 outputs the data signals Data_3r (=1) and Data_3f (=1) from the position indicated by the read pointer rdpt (=2).

When the chip clock signal ChipClock rises at time t4′, the Data_4r (=0) is fetched by the flip-flop FF4r, and the output data signal OutputData_r of the flip-flop FF4r is changed to “0”. At the same time, the Data_4f (=0) is fetched by the flip-flop FF4f, and the output data signal OutputData_f of the flip-flop FF4f is changed to “0”. Further, when the internal strobe signal Strobe2 rises, the Data_3r (=1) is fetched by the flip-flop FF3r, and the output data signal Data_4r of the flip-flop FF3r is changed to “1”. At the same time, the Data_3f (=1) is fetched by the flip-flop FF3f, and the output data signal Data_4f of the flip-flop FF3f is changed to “1”. When the internal strobe signal Strobe2 rises, the read pointer supply unit 92 updates the value of the read pointer rdpt to “0”. The FIFO 90 outputs the data signals Data_3r (=0) and Data_3f (=0) from the position indicated by the read pointer rdpt (=0).

When the chip clock signal ChipClock rises at time t5′, Data_4r (=1) is fetched by the flip-flop FF4r, and the output data signal OutputData_r of the flip-flop FF4r is changed to “1”. At the same time, the Data_4f (=1) is fetched by the flip-flop FF4f, and the output data signal OutputData_f of the flip-flop FF4f is changed to “1”. Further, when the internal strobe signal Strobe2 rises, the Data_3r (=0) is fetched by the flip-flop FF3r, and the output data signal Data_4r of the flip-flop FF3r is changed to “0”. At the same time, the Data_3f (=0) is fetched by the flip-flop FF3f, and the output data signal Data_4f of the flip-flop FF3f is changed to “0”.

When the chip clock signal ChipClock rises at time t6′, the Data_4r (=0) is fetched by the flip-flop FF4r, and the output data signal OutputData_r of the flip-flop FF4r is changed to “0”. At the same time, the Data_4f (=0) is fetched by the flip-flop FF4f, and the output data signal OutputData_f of the flip-flop FF4f is changed to “0”.

In this way, the data signal Data input at a double data rate is output as OutputData_r corresponding to the rising edge of the external strobe signal Strobe1, and is also as OutputData_f corresponding to the falling edge of the external strobe signal Strobe1.

Here, in general, there is a limitation on timing of setup time/hold time to allow the flip-flop to correctly receive data to generate an output signal. The setup time is the time during which the data signal must be stable before the strobe signal is input to the flip-flop. The hold time is the time during which the data signal must be stable after the strobe signal is input to the flip-flop. The data valid window is the area where the first arriving data signal and the last arriving data signal overlap, which can be calculated by subtracting the setup time and the hold time from one cycle of the strobe signal. Thus, there is a problem with using the flip-flop that the data signal may not be fetched if the data valid window of the data signal is narrow.

In the present embodiment, the data signal Data input from the outside is fetched by the flip-flop FF1 by using the strobe signal Strobe1 input from the outside. Thus, there is a problem of not being able to fetch the data signal Data if the data signal Data does not fit in the data valid window because of the degradation of the waveform of the data signal Data due to an increase in speed.

In the present embodiment, it takes as long as 3 UI to transfer a certain data signal Data from the timing of the external strobe signal Strobe1 to the internal strobe signal Strobe2. This is because the flip-flops FF1, FF2r, FF2f as well as the FIFO90 are used. In addition, after the data signal Data is transferred to the timing of the internal strobe signal Strobe2, it takes as long as 6 UI to output to the outside as OutputData_r and OutputData_f. This is because OutputData_r and OutputData_f are output through a two-stage flip-flop after the data signal Data is transferred to the timing of the internal strobe signal Strobe2.

For this reason, the latency, which is the time required for the output of the data signal Data that is input to the sample circuit 900 from the outside to the outside from the sample circuit 900, is 9 UI.

### Second Embodiment

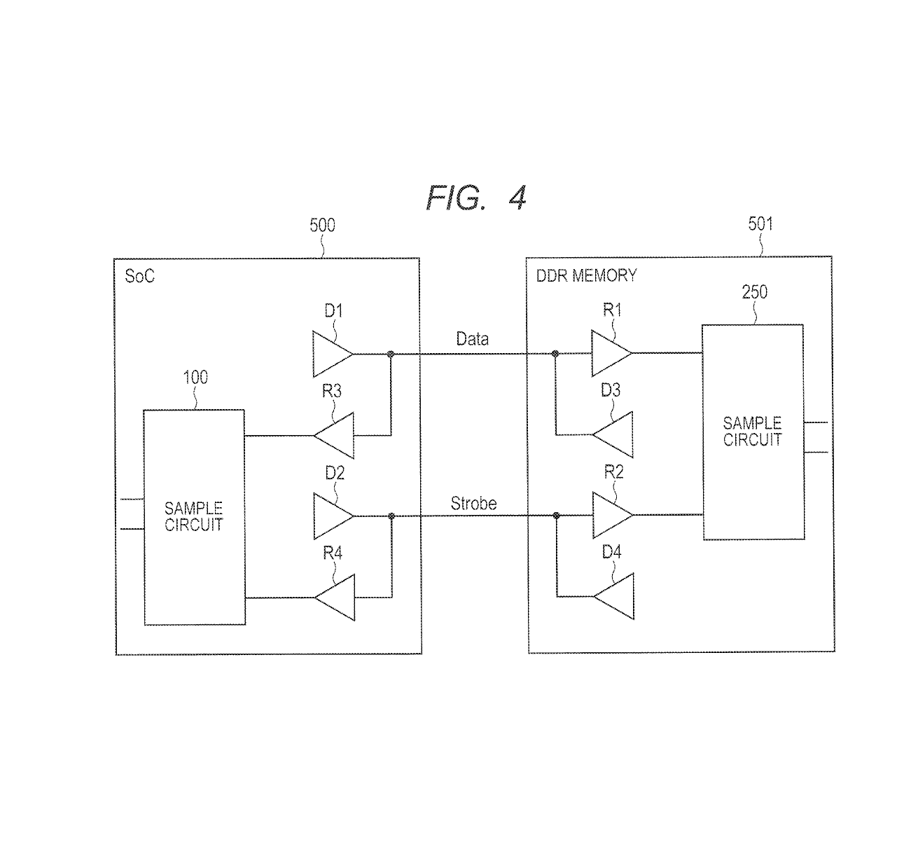

FIG. 4 is a diagram showing the configuration of a semiconductor device according to a second embodiment.

The semiconductor device includes an SoC (System-on-a-Chip) 500 and a DDR memory 501.

The SoC 500 includes a sample circuit 100, a driver D1, a driver D3, a receiver R3, and a receiver R4.

The DDR memory 501 includes a sample circuit 250, a driver D3, a driver D4, a receiver R1, and a receiver R2.

For example, when the data is read from a memory array, it is performed as follows.

Data output at a double data rate from a memory array, not shown, is transmitted to the receiver R3 by the driver D3. Then, the receiver R3 receives the data signal Data, and outputs to the sample circuit 100. Further, the driver D4 outputs a strobe signal Strobe. The receiver R4 receives the strobe signal Strobe, and outputs to the sample circuit 100. The sample circuit 100 outputs the data signal Data at a double data rate by sorting the data signal Data into two lanes by using the strobe signal Strobe.

Hereinafter, the configuration and operation of the sample circuit 100 will be described. The configuration and operation of the sample circuit 250 are the same as those of the sample circuit 100.

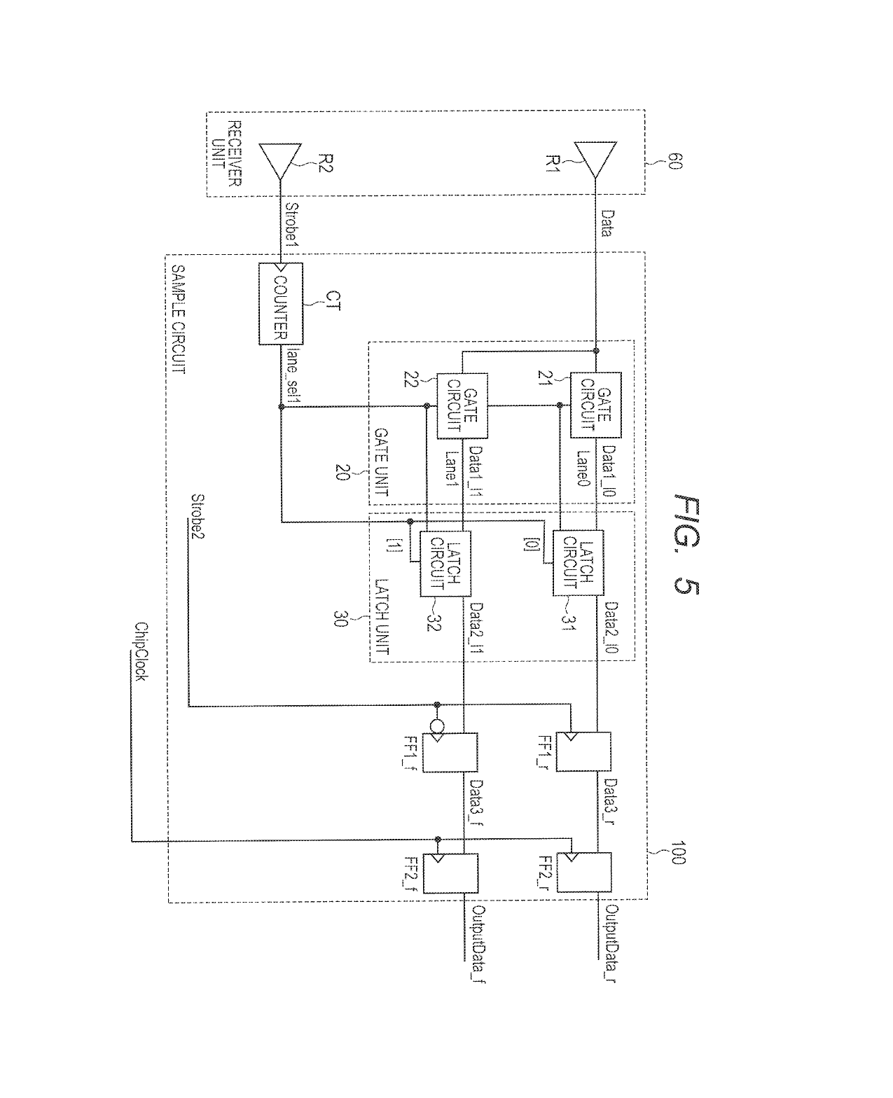

FIG. 5 is a diagram showing the configuration of the sample circuit 100 according to the second embodiment.

The sample circuit 100 includes a gate unit 20 including gate circuits 21 and 22, a latch unit 30 including latch circuits 31 and 32, flip-flops FF1_r and Ff1_f, flip-flops FF2_r and FF2_f, and a counter CT.

The sample circuit 100 receives the data signal Data that is output from the receiver R1 and transferred at a double data rate, as well as a strobe signal Strobe1 output from the receiver R2.

The counter CT is a first selection unit, which is a binary counter. The counter CT switches the level of the select signal lane_sel1 between “0” (low level) and “1” (high level) cyclically in synchronization with the timing of occurrence of the rising edge of the external strobe signal Strobe1 and the timing of occurrence of the falling edge of the external strobe signal Strobe1. At this time, the level “0” of the select signal lane_sel1 indicates that a first lane Lane0 is selected, while the level “1” of the select signal lane_sel1 indicates that a second lane Lane1 is selected.

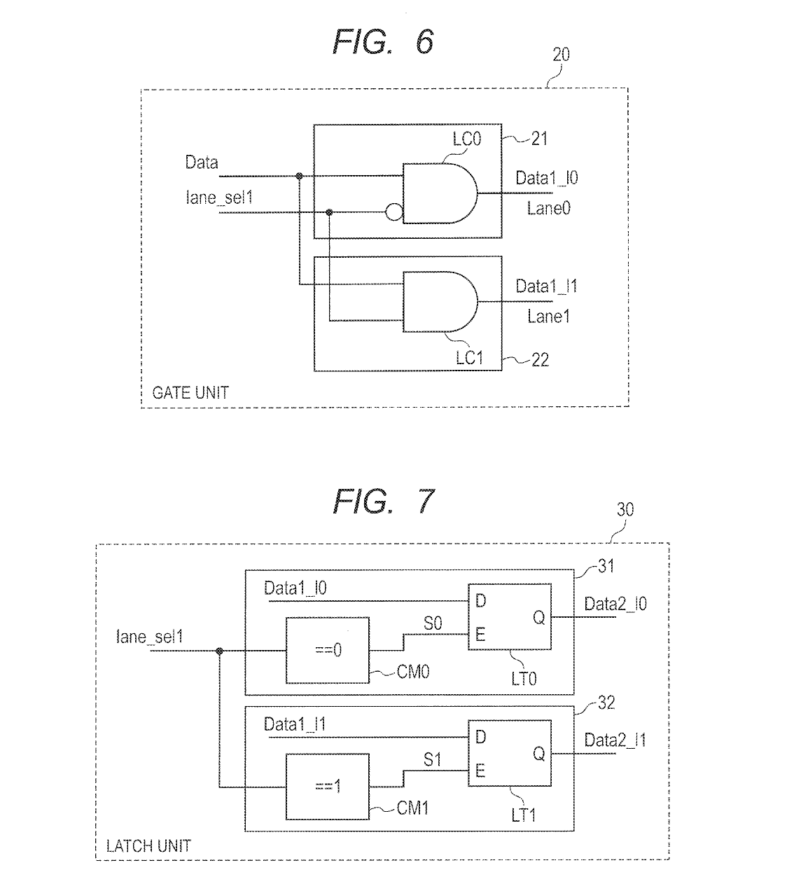

FIG. 6 is a diagram showing the configuration of the gate unit 20 according to the second embodiment.

The gate circuit 21 includes a logic circuit LC0. The logic circuit LC0 receives the data signal Data and the select signal lane_sel1. Then, the logic circuit LC0 outputs a signal Data1_IO, which represents the NAND operation of the data signal Data and the select signal lane_sel1, to the first lane Lane0.

The gate circuit 22 includes a logic circuit LC1. The logic circuit LC1 receives the data signal Data and the select signal lane_sel1. Then, the logic circuit LC1 outputs a signal Data1_I1, which represents the AND operation of the data signal Data and the select signal lane_sel1, to the second lane Lane1.

FIG. 7 is a diagram showing the configuration of the latch unit 30 according to the second embodiment.

The latch circuit 31 includes a comparator CM0 and a transmission latch LT0.

The transmission latch LT0 includes a data input terminal for receiving a data signal Data1_I0, and an enable terminal for receiving an output signal S0 of the comparator CM0. When the input signal S0 is at a high level, the transmission latch LT0 outputs the input data signal Data1_I0 directly as a data signal Data2_I0. When the input signal S0 is at a low level, the transmission latch LT0 outputs the data signal Data1_I0, which is held when the signal S0 is changed to the low level, as the data signal Data2_I0 regardless of the value of the input data signal Data1_I0.

The latch circuit 32 includes a comparator CM1 and a transmission latch LT1.

The comparator CM1 outputs a signal S1 of high level when the select signal lane_sel1 is “1”. Further, the comparator CM1 outputs a signal S1 of low level when the select signal lane_sel1 is other than “1”.

The transmission latch LT1 includes a data input terminal for receiving a data signal Data_I1, and an enable terminal for receiving an output signal S1 of the comparator CM1.

When the input signal S1 is at a high level, the transmission latch LT1 outputs the input data signal Data1_I1 directly as a data signal Data2_I1. When the input signal S1 is at a low level, the transmission latch LT1 outputs the data signal Data1_I1, which is held when the signal S1 is changed to the low level, as the data signal Data2_I1 regardless of the value of the input data signal Data1_I1.

The flip-flop FF1_r fetches the data signal Data2_I0, which is the output of the transmission latch LT0, in synchronization with the timing of occurrence of the rising edge of the internal strobe signal Strobe2 that is generated with the chip clock signal ChipClock through the gate circuit not shown. Then, the flip-flop FF1_r holds the data signal Data2_I0 and outputs as a data signal Data3_r. Further, the flip-flop FF1_f fetches the data signal Data2_I1, which is the output of the transmission latch LT1, in synchronization with the timing of occurrence of the falling edge of the internal strobe signal Strobe2. Then, the flip-flop FF1_f holds the data signal Data2_I1 and outputs as a data signal Data3_f.

The flip-flop FF2_r fetches the data signal Data3_r, which is the output of the flip-flop FF1_r, in synchronization with the timing of occurrence of the rising edge of the internally generated chip clock signal ChipClock. Then, the flip-flop FF2_r holds the data signal Data3_r and outputs as a data signal OutputData_r. The flip-flop FF2_f fetches the data signal Data3_f, which is the output of the flip-flop FF1_f, in synchronization with the timing of occurrence of the rising edge of the chip clock signal ChipClock. Then, the flip-flop FF2_f holds the data signal Data3_f and outputs as a data signal OutputData_f.

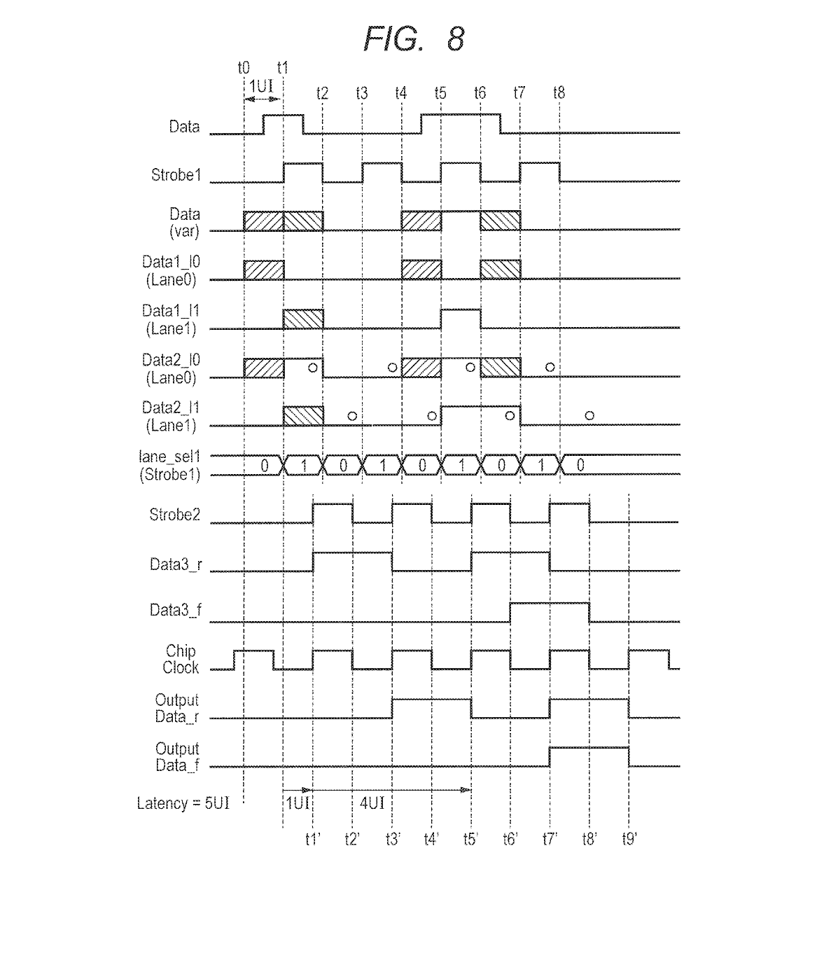

FIG. 8 is a timing diagram of the internal signals (data) of the sample circuit 100, the signals (data) input to the sample circuit 100, and the signals (data) output from the sample circuit 100 according to the second embodiment.

In FIG. 8, Data (var) is a waveform taking into account the degradation of the data signal Data (shadow area). In FIG. 8, it is assumed that the signal rises in any one of the diagonal lines rising from left to right, and that the signal falls in anyone of the diagonal lines rising from right to left. The circle mark indicates data to be fetched. The width of the data signal Data is 1 UI (Unit Interval)

The input data signal Data, the external strobe signal Strobe1, the internal strobe signal Strobe2, and the chip clock signal ChipClock vary at every 1 UI (Unit Interval). The variable timings of the input data signal Data, the external strobe signal Strobe1, and the internal strobe signal Strobe2 are not synchronized with each other. The internal strobe signal Strobe2 is substantially synchronized with the chip clock signal ChipClock. The sequence of the input data signal is “10001100”.

The select signal lane_sel1 is “0” at time t0≦t<t1. The input data signal Data is fetched by the gate circuit 21, and the data signal Data1_I0 is output to the first lane Lane0. At this time, the select signal lane_sel1 is “0”, so that the latch circuit 31 outputs the input data signal Data1_I0 directly as the data signal Data2_I0.

The external strobe signal Strobe1 rises at the time t1. When the counter CT switches the select signal lane_sel1 to “1”, the latch circuit 31 keeps the output data signal Data2_I0 at “1”. This is because the input data signal Data is changed to “1” at any timing before the time t1.

The select signal lane_sel1 is “1” at time t1≦t<t2. The input data signal Data is fetched by the gate circuit 22, and the data signal Data1_I1 is output to the second lane Lane1. At this time, the select signal lane_sel1 is “1”, so that the latch circuit 32 outputs the input data signal Data1_I1 directly as the data signal Data2_I1.

The external strobe signal Strobe1 falls at the time t2. When the counter CT switches the select signal lane_sel1 to “0”, the latch circuit 32 keeps the output data signal Data2_I1 at “0”. This is because the input data signal Data is changed to “0” at any timing after the time t1 and before the time t2.

The select signal lane_sel1 is “0” at time t2≦t<t3. The input data signal Data (=0) is fetched by the gate circuit 21, and the data signal Data1_I0 (=0) is output to the first lane Lane0. At this time, the select signal lane_sel1 is “0”, so that the latch circuit 31 outputs the input data signal Data1_I0 (=0) directly as the data signal Datat2_I0 (=0).

The external strobe signal Strobe1 rises at the time t3. When the counter CT switches the select signal lane_sel1 to “1”, the latch circuit 31 keeps the output data signal Data2_I0 at “0”.

The select signal lane_sel1 is “1” at time t3≦t<t4. The input data signal Data is fetched by the gate circuit 22, and the data signal Data1_I1 is output to the second lane Lane1. At this time, the select signal lane_sel1 is “1”, so that the latch circuit 32 outputs the input data signal Data1_I1 (=0) directly as the data signal Data2_I1 (=0).

The external strobe signal Strobe1 falls at the time t4. When the counter CT switches the select signal lane_sel1 to “0”, the latch circuit 32 keeps the output data signal Data2_I1 at “0”.

The select signal lane_sel1 is “0” at time t4≦t<t5. The input data signal Data is fetched by the gate circuit 21, and the data signal Data1_I0 is output to the first lane Lane0. At this time, the select signal lane_sel1 is “0”, so that the latch circuit 31 outputs the input data signal Data1_I0 directly as the data signal Data2_I0.

The external strobe signal Strobe1 rises at the time t5. When the counter CT switches the select signal lane_sel1 to “1”, the latch circuit 31 keeps the output data signal Data2_I0 at “1”. This is because the input data signal Data is changed to “1” at any timing after the time t4 and before the time t5.

The select signal lane_sel1 is “1” at time t5≦t<t6. The input data signal Data (=1) is fetched by the gate circuit 22, and the data signal Data1_I1 (=1) is output to the second lane Lane1. At this time, the select signal lane_sel1 is “1”, so that the latch circuit 32 outputs the input data signal Data1_I1 (=1) directly as the data signal Data2_I1 (=1).

The external strobe signal Strobe1 falls at the time t6. When the counter CT switches the select signal lane_sel1 to “0”, the latch circuit 32 keeps the output data signal Data2_I1 at “1”.

The select signal lane_sel1 is “0” at time t6≦t<t7. The input data signal Data is fetched by the gate circuit 21, and the data signal Data1_I0 is output to the first lane Lane0. At this time, the select signal lane_sel1 is “0”, so that the latch circuit 31 outputs the input data signal Data1_I0 directly as the data signal Data2_I0.

The external strobe signal Strobe1 rises at the time t7. When the counter CT switches the select signal lane_sel1 to “1”, the latch circuit 31 keeps the output data signal Data2_I0 at “0”. This is because the input data signal Data is changed to “0” at any timing after the time t6 and before the time t7.

The select signal lane_sel1 is “1” at time t7≦t<t8. The input data signal Data (=0) is fetched by the gate circuit 22, and the data signal Data1_I1 (=0) is output to the second lane Lane1. At this time, the select signal lane_sel1 is “1”, so that the latch circuit 32 outputs the input data signal Data1_I1 (=0) directly as the data signal Data2_I1 (=0).

The external strobe signal Strobe1 falls at the time t8. When the counter CT switches the select signal lane_sel1 to “0”, the latch circuit 32 keeps the output data signal Data2_I1 at “0”.

When the internal strobe signal Strobe2 rises at the time t1′, the Data2_I0 (=1) is fetched by the flip-flop FF1_r. Then, the output data signal Data3_r is changed to “1”.

When the internal strobe signal Strobe2 falls at the time t2′, the Data2_I1 (=0) is fetched by the flip-flop FF1_f. Then, the output data signal Data3_r is changed to “0”.

When the chip clock signal ChipClock rises at the time t3′, the Data 3_r (=1) is fetched by the flip-flop FF2_r, and the output data signal OutputData_r of the flip-flop FF2_r is changed to “1”. At the same time, the Data3_f (=0) is fetched by the flip-flop FF2_f, and the output data signal OutputData_f of the flip-flop FF2_f is changed to “0”. Further, when the internal strobe signal Strobe2 rises, the Data2_I0 (=0) is fetched by the flip-flop FF1_r. Then, the output data signal Data3_r is changed to “0”

When the internal strobe signal Strobe2 falls at the time t4′, the Data2_I1 (=0) is fetched by the flip-flop FF1_f. Then, the output data signal Data3_r is changed to “0”.

When the chip clock signal ChipClock rises at the time t5′, the Data3_r (=0) is fetched by the flip-flop FF2_r, and the output data signal OutputData_r of the flip-flop FF2_r is changed to “0”. At the same time, the Data3_f (=0) is fetched by the flip-flop FF2_f, and the output data signal OutputData_f of the flip-flop FF2_f is changed to “0”. Further, when the internal strobe signal Strobe2 rises, the Data2_I0 (=1) is fetched by the flip-flop FF1_r. Then, the output data signal Data3_r is changed to “1”.

When the internal strobe signal Strobe2 falls at the time t6′, the Data 2_I1 (=1) is fetched by the flip-flop FF1_r. Then, the output data signal Data3_r is changed to “1”.

When the chip clock signal ChipClock rises at the time t7′, the Data3_r (=1) is fetched by the flip-flop FF2_r, and the output data signal OutputData_r of the flip-flop FF2_r is changed to “1”. At the same time, the Data3_f (=1) is fetched by the flip-flop FF2_f, and the output data signal OutputData_f of the flip-flop FF2_f is changed to “1”. Further, when the internal strobe signal Strobe2 rises, the Data2_I0 (=0) is fetched by the flip-flop FF1_r. Then, the output data signal Data3_r is changed to “0”.

When the internal strobe signal Strobe2 falls at the time t8′, the Data2_I1 (=0) is fetched by the flip-flop FF1_f. Then, the output data signal Data3_r is changed to “0”.

When the chip clock signal ChipClock rises at the time t9′, the Data3_r (=0) is fetched by the flip-flop FF2_r, and the output data signal OutputData_r of the flip-flop FF2_r is changed to “0”. At the same time, the Data3_f (=0) is fetched by the flip-flop FF2_f, and the output data signal OutputData_f of the flip-flop FF2_f is changed to “0”.

As described above, the data signal Data input at a double data rate is output as the data signal OutputData_r corresponding to the rising edge of the Strobe1 of double data rate, and also as the data signal OutputData_f corresponding to the falling edge of the Strobe1.

In the present embodiment, the flip-flop is not used to fetch the data signal Data. Thus, the data signal Data does not need to fit in the data valid window that is specified by the setup time and hold time of the flip flop. In other words, it is possible to fetch the data signal Data by the latch unit 30, even if the waveform of the data signal Data is degraded with an increase in speed and, as shown in FIG. 8, even if the timing of the rising and falling edges varies by 1 UI (precisely, a value smaller than 1 UI by Δt (very little time)) as shown in FIG. 8.

In the present embodiment, it takes only 1 UI to transfer a certain data signal Data from the timing of the external strobe signal Strobe1 to the timing of the internal strobe signal Strobe2. This is because instead of using the flip-flops FF1, FF2r, and FF2f as well as the FIFO90 to fetch the data signal Data by using the external strobe signal Strobe1, it is designed to use the gate unit 20 and the latch unit 30 and use the external strobe signal Strobe1 to generate the select signal lane_sel1. In addition, after the data signal Data is transferred to the timing of the internal strobe signal Strobe2, it takes only 4 UI to output the data signal Data to the outside as OutputData_r and OutputData_f. This is because, after the data signal Data is transferred to the timing of the internal strobe signal Strobe2, OutputData_r and OutputData_f are output through a single-stage flip-flop. For this reason, the latency, which is the time required for the output of the data signal Data that is input to the sample circuit 100 from the outside to the outside from the sample circuit 100, is 5 UI.

As described above, according to the present embodiment, it is possible to achieve high frequency operation by improving the timing. In addition, it is possible to increase the operational performance by improving the latency. Further, in the present embodiment, it is possible to deal with dynamic changes in the input timing of the data signal.

### Third Embodiment

In a third embodiment, at least one of the sample circuits 100 and 250 of the second embodiment is replaced by a sample circuit 200.

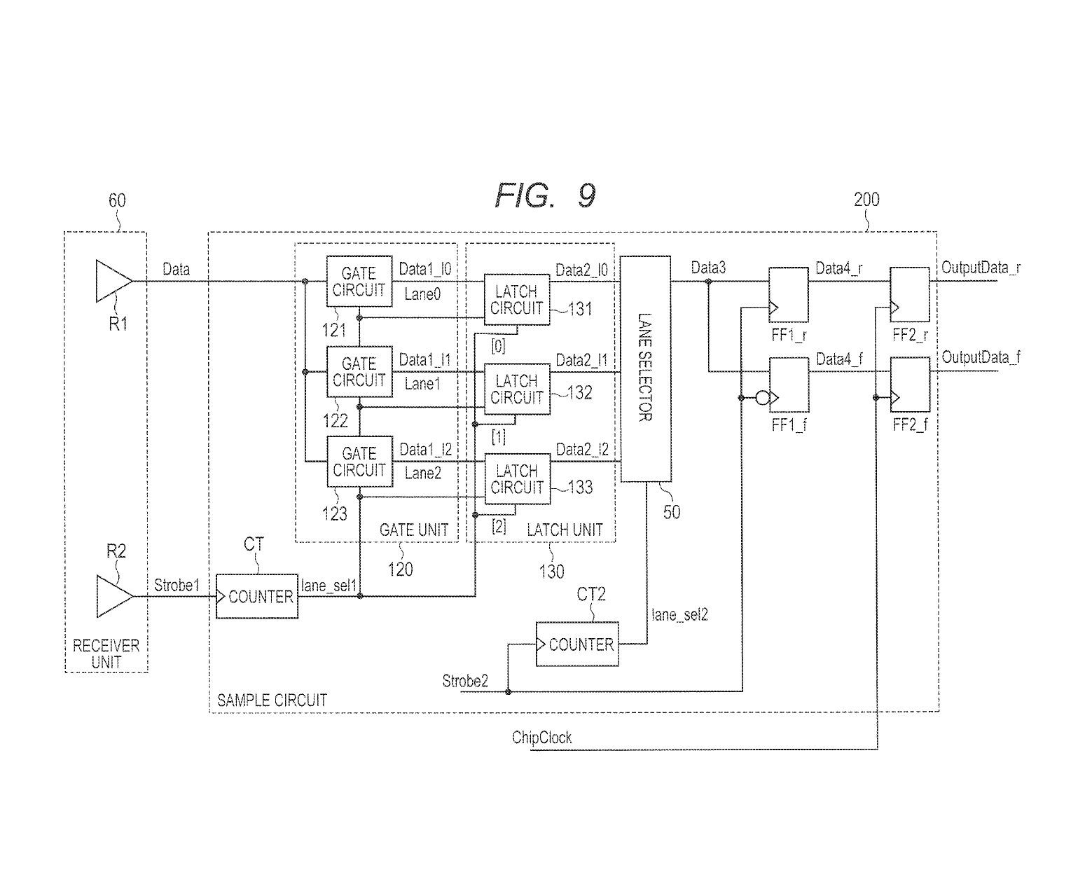

FIG. 9 is a diagram showing the configuration of the sample circuit 200.

The sample circuit 200 includes : a gate unit 120 including gate circuits 121, 122, and 123; a latch unit 130 including latch circuits 131, 132, and 133; flip-flops FF1_r and FF1_f; flip-flops FF2_r and FF2_f; and counters CT and CT2.

The sample circuit 200 receives the data signal Data that is output from the receiver R1 and transferred at a double data rate, as well as the external strobe signal Strobe1 output from the receiver R2.

The counter CT is a first selection unit which is a ternary counter. The counter CT increases the value of the select signal lane_sel1 by “1” in synchronization with the timing of occurrence of the rising edge of the external strobe signal Strobe1 as well as the timing of occurrence of the falling edge of the external strobe signal Strobe1. When the value of the select signal lane_sel1 is “0”, it indicates that the first lane Lane0 is selected. When the value of the select signal lane_sel1 is “1”, it indicates that the second lane Lane1 is selected. Further, when the value of the select signal lane_sel1 is “2”, it indicates that a third lane Lane2 is selected.

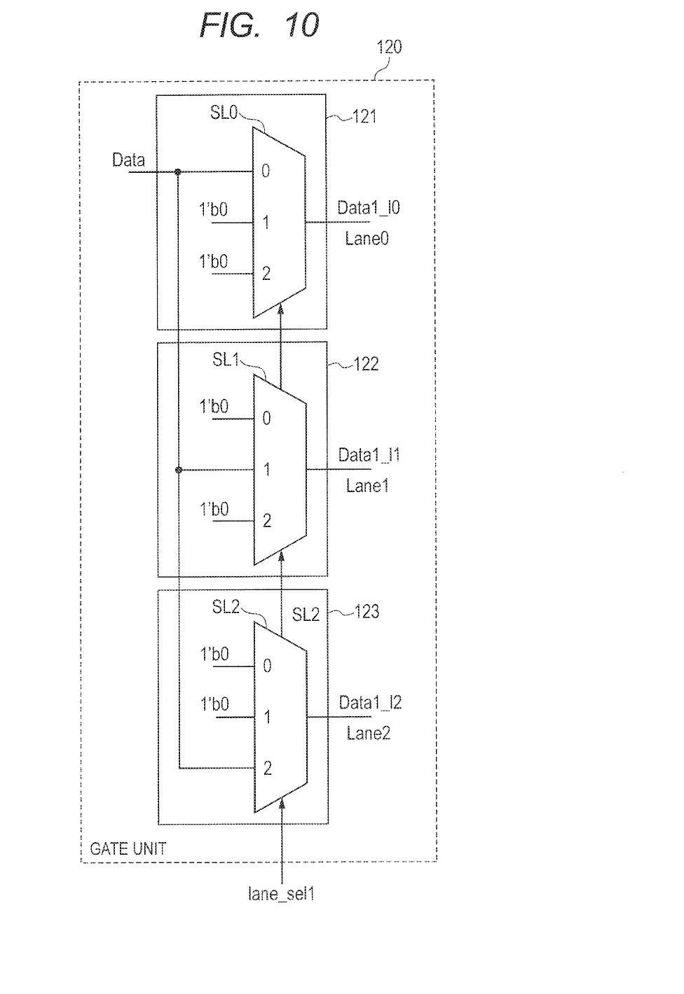

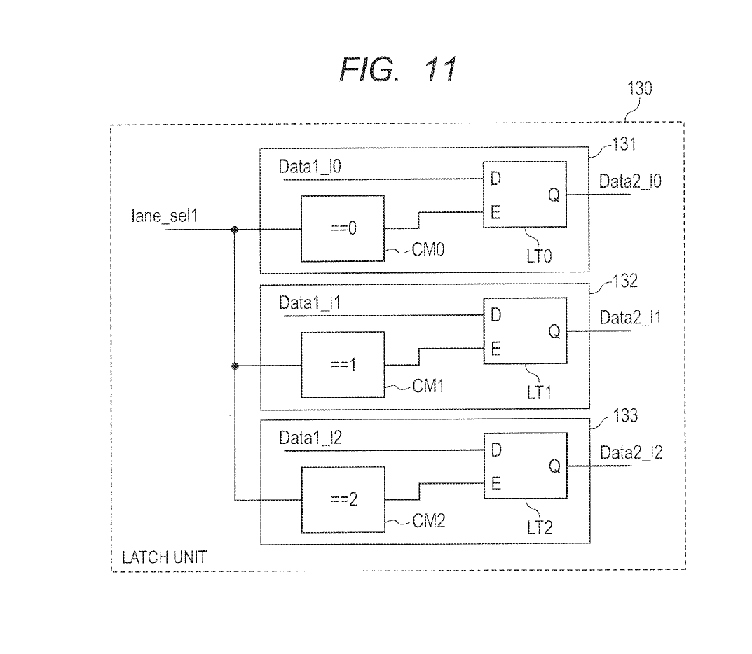

FIG. 10 is a diagram showing the configuration of the gate unit 120 according to the third embodiment.

The gate circuit 121 includes a first selector SL0.

In the first selector SL0, the 0th input terminal receives a data signal Data. Then, the first input terminal receives a 1 bit data 1′b0 with the value 0, and the second input terminal receives a 1 bit data 1′b0 with the value 0. When the value of the select signal lane_sel1 is “0” (first value), the first selector SL0 outputs the input data signal Data to the first lane Lane0 directly as a data signal Data1_I0. On the other hand, when the value of the select signal lane_sel1 is “1” or “2” (other than the first value), the first selector SL0 outputs the 1 bit data 1′b0 to the first lane Lane0 as the data signal Data1_IO.

The gate circuit 122 includes a second selector SL1.

In the second selector SL1, the 0th input terminal receives the 1 bit data 1′b0 with the value 0. Then, the first input terminal receives the data signal Data, and the second input terminal receives the 1 bit data 1′b0 with the value 0. When the value of the select signal lane_sel1 is “1” (second value), the second selector SL1 outputs the input data signal Data to the second lane Lane1 directly as a data signal Data1_I1. On the other hand, when the value of the select signal lane_sel1 is “0” or “2” (other than the second value), the second selector SL1 outputs the 1 bit data 1′b0 to the second lane Lane1 as the data signal Data1_I1.

The gate circuit 123 includes a third selector SL2.

In the third selector SL2, the 0th input terminal receives the 1 bit data 1′b0 with the value 0. Then, the first input terminal receives the 1 bit data 1′b0 with the value 0, and the second input terminal receives the data signal Data. When the value of the select signal lane_sel1 is “2” (third value), the third selector SL2 outputs the input data signal Data to the third lane Lane2 directly as a data signal Data1_I2. On the other hand, when the value of the selector signal lane_sel1 is “0” or “1” (other than the third value), the third selector SL2 outputs the 1 bit data 1′b0 to the third lane Lane2 as the data signal Data1_I2.

FIG. 11 is a diagram showing the configuration of the latch unit 130 according to the third embodiment.

The latch circuit 131 includes a first comparator CM0 and a first transmission latch LT0.

When the value of the select signal lane_sel1 is “0” (first value), the first comparator CM0 outputs a signal S0 of high level. When the value of the select signal lane_sel1 is other than “0” (other than the first value), the first comparator CM0 outputs a signal S0 of low level.

The first transmission latch LT0 includes a data input terminal for receiving the data signal Data_I0, as well as an enable terminal for receiving the output signal S0 of the first comparator CM0. When the input signal S0 is at a high level, the first transmission latch LT0 outputs the input data signal Data1_I0 directly as a data signal Data2_I0. When the input signal S0 is at a low level, the first transmission latch LT0 outputs the input data signal Data1_I0, which is held when the signal S0 is changed to the low level, as the data signal Data2_I0 regardless of the value of the input data signal Data1_I0.

The latch circuit 132 includes a second comparator CM1 and a second transmission latch LT1.

When the value of the select signal lane_sel1 is “1” (second value), the second comparator CM1 outputs a signal S1 of high level. When the value of the select signal lane_sel1 is other than “1” (other than the second value), the second comparator CM1 outputs a signal S1 of low level.

The second transmission latch LT1 includes a data input terminal for receiving the data signal Data_I1, as well as an enable terminal for receiving the output signal S1 of the second comparator CM1. When the input signal S1 is at a high level, the second transmission latch LT1 outputs the input data signal Data1_I1 directly as a data signal Data2_I1. When the input signal S1 is at a low level, the second transmission latch LT1 outputs the data signal Data1_I1, which is held when the signal S1 is changed to the low level, as the data signal Data2_I1 regardless of the value of the input data signal Data1_I1.

The latch circuit 133 includes a third comparator CM2 and a third transmission latch LT2.

When the value of the select signal lane_sel1 is “2” (third value), the third comparator CM2 outputs a signal S2 of high level. When the value of the select signal lane_sel1 is other than “2” (other than the third value), the third comparator CM2 outputs a signal S2 of low level.

The third transmission latch LT2 includes a data input terminal for receiving data signal Data_I2, as well as an enable terminal for receiving the output signal S2 of the third comparator CM2. When the input signal S2 is at a high level, the third transmission latch LT2 outputs the input data signal Data1_I2 directly as a data signal Data2_I2. When the value of the input signal S2 is at a low level, the transmission latch LT2 outputs the data signal Data1_I2, which is held when the signal S2 is changed to the low level, as the data signal Data2_I2 regardless of the value of the input data signal Data1_I2.

The counter CT2 is a second selection unit which is a ternary counter.

The counter CT2 increases the value of the select signal lane_sel2 by “1” in synchronization with the timing of occurrence of the rising edge of the internal strobe signal Strobe2 as well as the timing of occurrence of the falling edge of the internal strobe signal Strobe2. When the value of the select signal lane_sel2 is “0”, it indicates that the output of the first transmission latch LT0 is selected. When the value of the select signal lane_sel2 is “1”, it indicates that the output of the second transmission latch LT1 is selected. Further, when the value of the select signal lane_sel2 is “2”, it indicates that the output of the third transmission latch LT2 is selected.

A lane selector 50 receives the select signal lane_sel2 as well as the data signals Data2_I0, Data2_I1, and Data2_I2. When the value of the select signal lane_sel2 is “0”, the lane selector 50 outputs the data signal Data2_I0, which is the output of the first transmission latch LT0, as a data signal Data3. When the value of the select signal lane_sel2 is “1”, the lane selector 50 outputs the data signal Data2_I1, which is the output of the second transmission latch LT1, as the data signal Data3. Further, when the value of the select signal lane_sel2 is “2”, the lane selector 50 outputs the data signal data2_I2, which is the output of the second transmission latch LT1, as the data signal Data3.

The flip-flop FF1_r fetches the data signal Data3 in synchronization with the timing of occurrence of the rising edge of the internal strobe signal Strobe1. Then, the flip-flop FF1_r holds the data signal Data3 and outputs as a data signal Data4_r.

The flip-flop FF1_f fetches the data signal Data3 in synchronization with the timing of occurrence of the falling edge of the internal strobe signal Strobe2. Then, the flip-flop FF1_f holds the data signal Data3 and outputs as a data signal Data4_f.

The flip-flop FF2_r fetches the data signal Data4_r in synchronization with the timing of occurrence of the rising edge of the chip clock signal ChipClock. Then, the flip-flop FF2_r holds the data signal Data4_r and outputs as a data signal OutputData_r.

The flip-flop FF2_f fetches the data signal Data4_f in synchronization with the timing of occurrence of the rising edge of the chip clock signal ChipClock. Then, the flip-flop FF2_f holds the data signal Data4_f and outputs as a data signal OutputData_f.

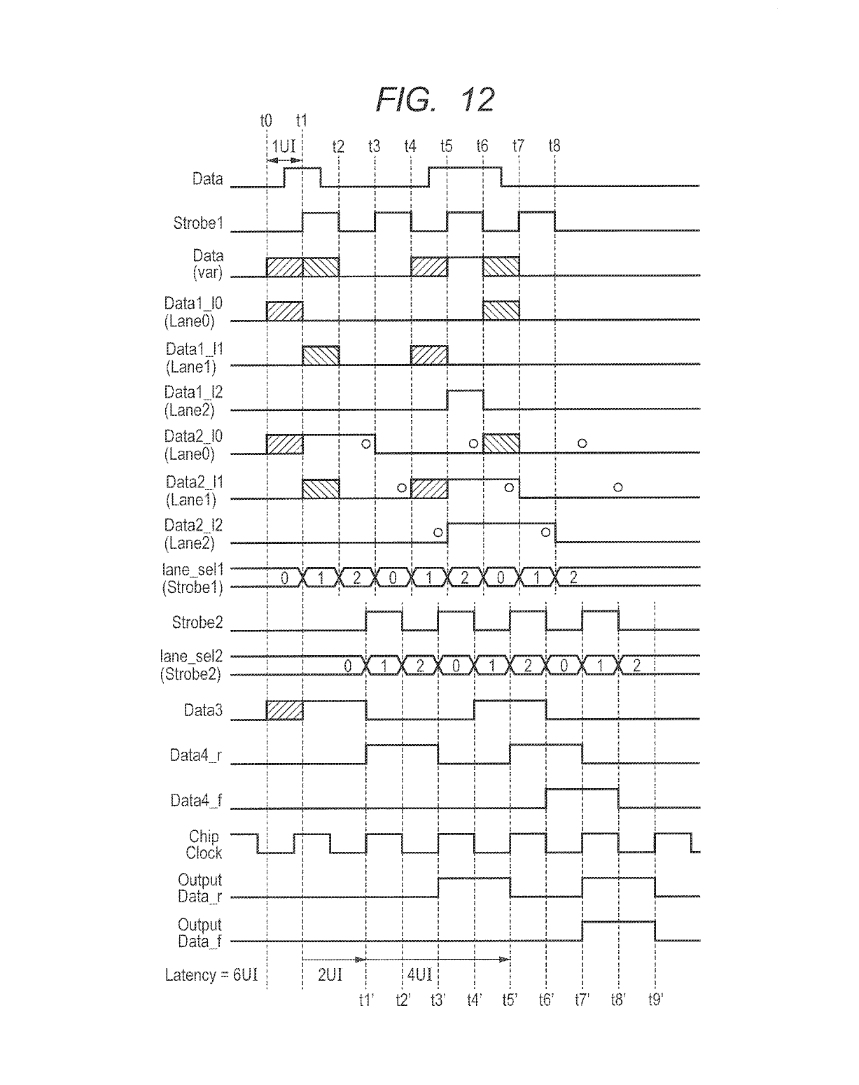

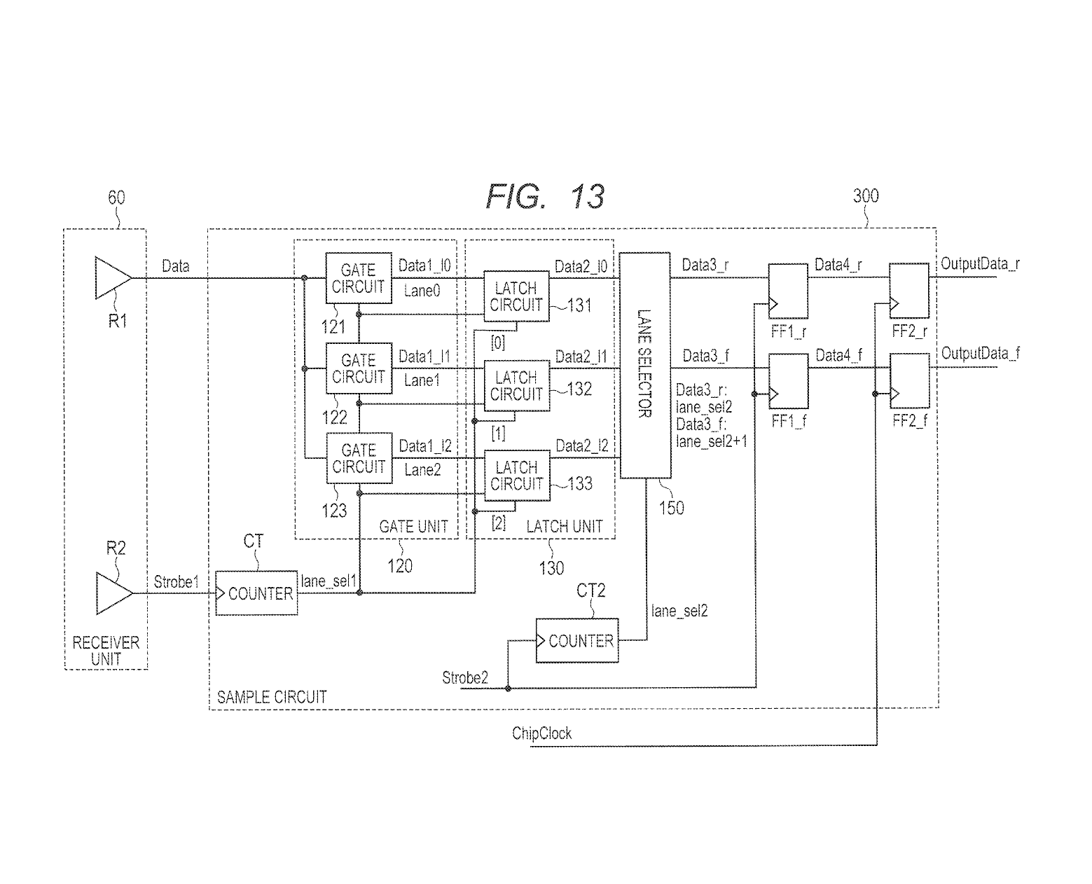

FIG. 12 is a timing diagram of the internal signals (data) of the sample circuit 200, the signals (data) input to the sample circuit 200, and the signals (data) output from the sample circuit 200 according to the third embodiment.

In FIG. 12, Data (var) is a waveform taking into account the degradation of the data signal Data (shadow area). In FIG. 12, it is assumed that the signal rises in any one of the diagonal lines rising from left to right, and that the signal falls in any one of the diagonal lines rising from right to left. The circle mark indicates data to be fetched. The width of the data signal data is 1 UI (Unit Interval).

The input data signal Data, the external strobe signal Strobe1, the internal strobe signal Strobe2, and the chip clock signal ChipClock vary at every 1 UI (Unit Interval). The variable timings of the input data signal Data, the external strobe signal Strobe1, and the internal strobe signal Strobe2 are not synchronized with each other. The internal strobe signal Strobe2 is substantially synchronized with the chip clock signal ChipClock. The sequence of the input data signal is “10001100”.

The select signal lane_sel1 is “0” at time t0≦t<t1. The input data signal Data is fetched by the gate circuit 121, and the data signal Data1_I0 is output to the first lane Lane0. At this time, the select signal lane_sel1 is “0”, so that the latch circuit 131 outputs the input data signal Data1_I0 directly as the data signal Data2_I0.

The external strobe signal strobe1 rises at the time t1. When the counter CT switches the select signal lane_sel1 to “1”, the latch circuit 131 keeps the data signal data2_I0 at “1”. This is because the input data signal Data is changed to “1” at any timing before the time t1.

The select signal lane_sel1 is “1” at time t1≦t<t2. The input data signal Data is fetched by the gate circuit 122, and the data signal Data1_I1 is output to the second lane Lane1. At this time, the select signal lane_sel1 is “1”, so that the latch circuit 132 outputs the input data signal Data1_I1 directly as the data signal Data2_I1.

The external strobe signal Strobe1 falls at the time t2. When the counter CT switches the select signal lane_sel1 to “2”, the latch circuit 132 keeps the output data signal Data2_I1 at “0”. This is because the input data signal Data is changed to “0” at any timing after the time t1 and before the time t2.

The selector signal lane_sel1 is “2” at time t2≦t<t3. The input data signal Data (=0) is fetched by the gate circuit 123, and the data signal Data1_I2 (=0) is output to the third lane Lane2. At this time, the select signal lane_sel1 is “2”, so that the latch circuit 133 outputs the input data signal Data1_I2 (=0) directly as the data signal Data2_I2 (=0).

The external strobe signal Strobe1 rises at the time t3. When the counter CT switches the select signal lane_sel1 to “0”, the latch circuit 133 keeps the output data signal Data2_I2 at “0”.

The select signal lane_sel1 is “0” at time t3≦t<t4. The input data signal Data is fetched by the gate circuit 121, and the data signal data1_I0 is output to the first lane Lane0. At this time, the select signal lane_sel1 is “0”, so that the latch circuit 131 outputs the input data signal Data1_I0 (=0) directly as the data signal Data2_I0 (=0).

The external strobe signal Strobe1 falls at the time t4. When the counter CT switches the select signal lane_sel1 to “1”, the latch circuit 131 keeps the output data signal Data2_I0 at “0”.

The select signal lane_sel1 is “1” at time t4≦t<t5. The input data signal Data is fetched by the gate circuit 122, and the data signal Data1_I1 is output to the second lane Lane1. At this time, the select signal lane_sel1 is “1”, so that the latch circuit 132 outputs the input data signal Data1_I1 directly as the signal Data2_I1.

The external strobe signal Strobe1 rises at the time t5. When the counter CT switches the select signal lane_sel1 to “2”, the latch circuit 132 keeps the output data signal Data2_I1 at “1”. This is because the input data signal Data is changed to “1” at any timing after the time t4 and before the time t5.

The select signal lane_sel1 is “2” at time t5≦t<t6. The input data signal Data (=1) is fetched by the gate circuit 123, and the data signal Data1_I2 (=1) is output to the third lane Lane2. At this time, the select signal lane_sel1 is “2”, so that the latch circuit 133 outputs the input data signal Data1_I2 (=1) directly as the data signal Data2_I2 (=1).

The external strobe signal Strobe1 falls at the time t6. When the counter CT switches the select signal lane_sel1 to “0”, the latch circuit 133 keeps the output data signal Data2_I2 at “1”.

The select signal lane_sel1 is “0” at time t6≦t<t7. The input data signal Data is fetched by the gate circuit 121, and the data signal Data1_I0 is output to the first lane Lane0. At this time, the select signal lane_sel1 is “0”, so that the latch circuit 131 outputs the input data signal Data1_I0 directly as the data signal Data2_I0.

The external strobe signal Strobe1 rises at the time t7. When the counter CT switches the select signal lane_sel1 to “1”, the latch circuit 131 keeps the output data signal Data2_I0 at “0”. This is because the input data signal Data is changed to “0” at any timing after the time t6 and before the time t7.

The select signal lane_sel1 is “1” at time t7≦t<t8. The input data signal Data (=0) is fetched by the gate circuit 122, and the data signal Data1_I1 (=0) is output to the second lane Lane1. At this time, the select signal lane_sel1 is “1”, so that the latch circuit 132 outputs the input data signal Data1_I1 (=0) directly as the data signal Data2_I1 (=0).

The external strobe signal Strobe1 falls at the time t8. When the counter CT switches the select signal lane_sel1 to “2”, the latch circuit 132 keeps the output data signal Data2_I1 at “0”.

The select signal lane_sel2 is “0” at any timing after the time t2 and before the time t1′, so that the lane selector 50 selects the data signal Data2_I0 (=1) and outputs as the data signal Data3 (=1).

The internal strobe signal strobe2 rises at the time t1′. When the counter CT2 switches the select signal lane_sel2 to “1”, the lane selector 50 selects the data signal Data2_I1 (=0), and outputs as the data signal Data3 (=0).

The internal strobe signal Strobe2 falls at the time t2′. When the counter CT2 switches the select signal lane_sel2 to “2”, the lane selector 50 selects the data signal Data2_I2 (=0), and outputs as the data signal Data3 (=0).

When the chip clock signal ChipClock rises at the time t3′, the Data4_r (=1) is fetched by the flip-flop FF2_r. Then, the output data signal OutputData_r of the flip-flop FF2_r is changed to “1”. At the same time, the Data4_f (=0) is fetched by the flip-flop FF2_f. Then, the output data signal OutputData_f of the flip-flop FF2_f is changed to “0”. Further, when the internal strobe signal Strobe2 rises and when the counter CT2 switches the select signal lane_sel2 to “0”, the lane selector 50 selects the data signal Data2_I0 (=0) and outputs as the data signal Data3 (=0).

The internal strobe signal Strobe2 falls at the time t4′. When the counter CT2 switches the select signal lane_sel2 to “1”, the lane selector 50 selects the data signal Data2_I1 (=1) and outputs as the data signal Data3 (=1).

When the chip clock signal ChipClock rises at the time t5′, the Data4_r (=0) is fetched by the flip-flop FF2_r. Then, the output data signal OutputData_r of the flip-flop FF2_r is changed to “0”. At the same time, the Data4_f (=0) is fetched by the flip-flop FF2_f. Then, the output data signal OutputData_f of the flip-flop FF2_f is changed to “0”. Further, when the internal strobe signal Strobe2 rises and when the counter CT2 switches the select signal lane_sel2 to “2”, the lane selector 50 selects the data signal Data2_I2 (=1) and outputs as the data signal Data3 (=1).

The internal strobe signal Strobe2 falls at the time t6′. When the counter CT2 switches the select signal lane_sel2 to “0”, the lane selector 50 selects the data signal Data2_I0 (=0) and outputs as the data signal Data3 (=0).

When the chip clock signal ChipClock rises at the time t7′, the Data4_r (=1) is fetched by the flip-flop FF2_r. Then, the output data signal OutputData_r of the flip-flop FF2_r is changed to “1”. At the same time, the Data4_f (=1) is fetched by the flip-flop FF2F_f. Then, the output data signal OutputData_f of the flip-flop FF2_f is changed to “1”. Further, when the internal strobe signal Strobe2 rises and when the counter CT2 switches the select signal lane_sel2 to “1”, the lane selector 50 selects the data signal Data2_I1 (=0) and outputs as the data signal Data3 (=1).

When the chip clock signal ChipClock rises at the time t9′, the Data4_r (=0) is fetched by the flip-flop FF2_r. Then, the output data signal OutputData_r of the flip-flop FF2_r is changed to “0”. At the same time, the Data4_f (=0) is fetched by the flip-flop FF2_f. Then, the output data signal OutputData_f of the flip-flop FF2_f is changed to “0”.

As described above, the data signal Data input at a double data rate is output as the data signal OutputData_r corresponding to the rising edge of the Strobe1 of double data rate, and also as the data signal OutputData_f corresponding to the falling edge of the Strobe1.

In the present embodiment, similarly to the second embodiment, as shown in FIG. 12, even when the timing of the rising and falling edges varies by 1 UI (precisely, a value smaller than 1 UI by Δt (very little time)), it is possible to fetch the data signal Data by the latch unit 30.

In the present embodiment, it takes 2 UI to transfer a certain data signal Data from the timing of the external strobe signal Strobe1 to the timing of the internal strobe signal Strobe2. The reason why it takes longer than 1 UI in the second embodiment is because the number of lanes is increased from two to three. The time for transfer is set to 2 UI to allow the data signal Data to be reliably transferred from the external strobe signal Strobe1 to the timing of the internal strobe signal Strobe2, even if the difference in the timing between the external strobe signal Strobe1 and the internal strobe signal Strobe2 is large.

Further, similarly to the second embodiment, it takes 4 UI for outputting the data signal Data to the outside as OutputData_r and OutputData_f after the data signal Data is transferred to the internal strobe signal Strobe2. This is because, similarly to the second embodiment, the data signal Data is first transferred to the internal strobe signal Strobe2 and then OutputData_r and OutputData_f are output through a single-stage flip-flip. For this reason, the latency, which is the time required for the output of the data signal Data, that is input from the outside to the sample circuit 200, to the outside from the sample circuit 200, is 6 UI.

Note that it is assumed that the sample circuit of FIG. 9 includes three lanes. However, the present invention is not limited to this example, and the sample circuit may include N lanes.

When the sample circuit includes N lanes, the select signal lane_sel1 is generated by a first N-ary counter. The gate unit includes N gate circuits and the latch unit includes N latch circuits, in which the lane selector selects and outputs one of the outputs of the N latch circuits according to a select signal lane_sel2 output from a second N-ary counter.

More specifically, the first N-ary counter increases the value of the select signal lane_sel1 by “1” in synchronization with the timing of the rising and falling edges of the strobe signal Strobe1.

The gate unit includes first to Nth selectors. An i-th selector (i=1 to N) outputs a data signal when the value of the select signal lane_sel1 is an i-th value (=i-1). Then, the i-th selector outputs 0 when the value of the select signal lane_sel1 is other than the i-th value.

The latch unit includes first to N comparison circuits as well as first to N transmission latches.

An i-th comparison circuit (i=1 to N) compares the value of the select signal lane_sel1 with the i-th value (=i-1). Then, the i-th comparison circuit outputs a high level signal when the two values are the same, and outputs a low level signal when the two values are different.

An i-th transmission latch (i=1 to N) includes a data input terminal for receiving a data signal, as well as an enable terminal for receiving the output signal of the i-th comparison circuit.

The second N-ary counter generates the select signal lane_sel2 that indicates which one of the outputs of the first to Nth transmission latches is selected according to the internal strobe signal Strobe2. The second N-ary counter increases the value of the select signal lane_sel2 by “1” in synchronization with the timing of the rising and falling edges of the internal strobe signal Strobe2.

The lane selector receives the outputs of the first to Nth transmission latches. Then, the lane selector outputs one of the outputs of the first to Nth transmission latches based on the value of the select signal lane_sel2.

When the number of lanes is N, the configuration and operation of the flip-flops FF1_r, FF1_f, FF2_r, and FF2_f are the same as when the number of lanes is 2.

### Fourth Embodiment

In a fourth embodiment, at least one of the sample circuits 100 and 250 of the second embodiment is replaced by a sample circuit 300.

FIG. 13 is a diagram showing the configuration of the sample circuit 300 according to the fourth embodiment.

The sample circuit 300 includes: the gate unit 120 including the gate circuits 121, 122, and 123; the latch unit 130 including the latch circuits 131, 132, and 133; a lane selector 150; the flip-flops FF1_r and FF1_f; the flip-flops FF2_r and FF2_f; and the counters CT and CT2.

The sample circuit 300 receives the data signal Data that is output from the receiver R1 and transferred at a double data rate, as well as the external strobe signal Strobe1 output from the receiver R2.

The counter CT, the gate unit 120, and the latch unit 130 are the same as those of the third embodiment, and the description will not be repeated here.

The counter CT2 is a second selection unit which is a ternary counter.

The counter CT2 increases the value of the select signal lane_sel2 by “2” in synchronization with the timing of occurrence of the rising edge of the internal strobe signal Strobe2. The value of the select signal lane_sel2 indicates a first output of the lane selector 150. Further, the value obtained by adding “1” to the value of the select signal lane_sel2 indicates a second output of the lane selector 150. Note that, however, this value also cyclically increased by a value between 0 and 2 similarly to the select signal lane_sel2.

When the value of the select signal lane_sel2 is “0”, it indicates that the output of the first transmission latch LT0 is selected as the first output and the output of the second transmission latch LT1 is selected as the second output. When the value of the select signal lane_sel2 is “1”, it indicates that the output of the second transmission latch LT1 is selected as the first output and the output of the third transmission latch LT2 is selected as the second output. Further, when the value of the select signal lane_sel2 is “2”, it indicates that the output of the third transmission latch LT2 is selected as the first output and the output of the first transmission latch LT0 is selected as the second output.

The lane selector 150 receives the select signal lane_sel2 as well as the data signals Data2_I0, Data2_I1, and Data2_I2. When the value of the select signal lane_sel2 is k, the lane selector 150 outputs a data signal Data2_Ik as a first output data signal Data_3r, and outputs a data signal Data2_Ij as a second output data signal Data_3f. Note that j is a number cyclically increased between “0” to “2” (ternary number), which is greater than k by 1.

In other words, when the value of the select signal lane_sel2 is “0”, the lane selector 150 outputs the data signal Data2_I0, which is the output of the first transmission latch LT0, as the first output data signal Data3_r, and also outputs the data signal Data2_I1, which is the output of the second transmission latch LT1, as the second output data signal Data3_f. When the value of the select signal lane_sel2 is “1”, the lane selector 150 outputs the data signal Data2_I1, which is the output of the second transmission latch LT1, as the first output data signal Data3_r, and also outputs the data signal Data2_I2, which is the output of the third transmission latch LT2, as the second output data signal Data3_f. Further, when the value of the select signal lane_sel2 is “2”, the lane selector 150 outputs the data signal Data2_I2, which is the output of the third transmission latch LT2, as the first output data signal Data3_r, and also outputs the data signal Data2_I0, which is the output of the first transmission latch LT0, as the second output data signal Data3_f.

The flip-flop FF1_r fetches the data signal Data3_r in synchronization with the timing of occurrence of the rising edge of the internal strobe signal Strobe2. Then, the flip-flop FF1_r holds the data signal Data3_r and outputs as the data signal Data4_r. The flip-flop FF1_f fetches the data signal Data3_f in synchronization with the timing of occurrence of the rising edge of the internal strobe signal Strobe2. Then, the flip-flop FF1_f holds the data signal Data3_f and outputs as the data signal Data4_f.

The flip-flop FF2_r fetches the data signal Data4_r in synchronization with the timing of occurrence of the rising edge of the chip clock signal ChipClock. Then, the flip-flop FF2_r holds the data signal Data4_r and outputs as the data signal OutputData_r. The flip-flop FF2_f fetches the data signal Data4_f in synchronization with the timing of occurrence of the rising edge of the chip clock signal ChipClock. Then, the flip-flop FF2_f holds the data signal Data4_f and outputs as the data signal OutputData_f.

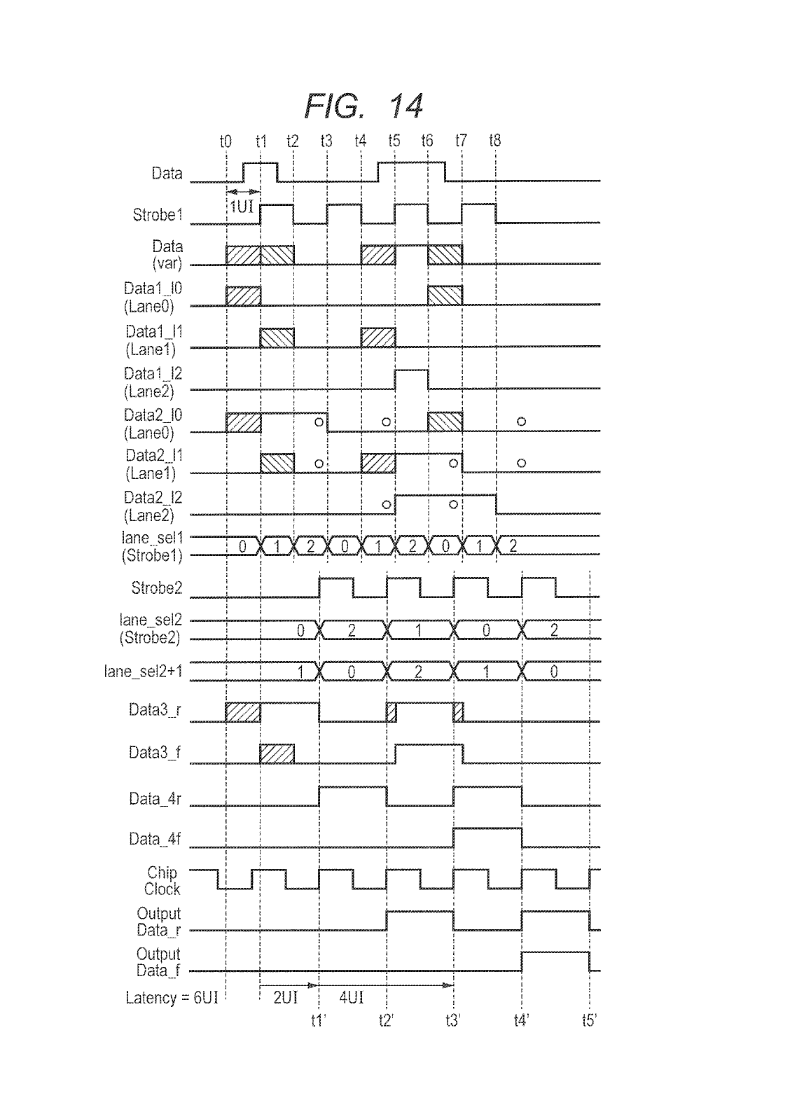

FIG. 14 is a timing diagram of the internal signals (data) of the sample circuit 300, the signals (data) input to the sample circuit 300, and the signal (data) output from the sample circuit 300 according to the fourth embodiment.

In FIG. 14, Data (var) is a waveform taking into account the degradation of the data signal Data (shadow area). In FIG. 14, it is assumed that the signal rises in any one of the diagonal lines rising from left to right, and that the signal falls in any one of the diagonal lines rising from right to left. The circle mark indicates data to be fetched. The width of the data signal Data is 1 UI (Unit Interval).

The select signal lane_sel2 is “0” at any timing after the time t2 and before the time t1′, so that the lane selector 150 selects the data signal Data2_I0 (=1) and outputs as the data signal Data3_r (=1). Further, the value of the select signal lane_sel2+1 is “1”, so that the lane selector 150 selects the data signal Data2_I1 (=0) and outputs as the data signal Data3_f (=1).

When the internal strobe signal Strobe2 rises at the time t1′, the Data3_r (=1) is fetched by the flip-flop FF1_r. Then, the output data signal Data4_r of the flip-flop FF1_r is changed to “1”. At the same time, the Data3_f (=0) is fetched by the flip-flop FF1_f, and the output data signal Data4_f of the flip-flop FF1_f is changed to “0”. Further, when the internal strobe signal Strobe2 rises and when the counter CT2 switches the select signal lane_sel2 to “2”, the lane selector 150 selects the data signal Data2_I2 (=0) and outputs as the data signal Data3_r (=0). At this time, the value of the select signal lane_sel2+1 is “0”, so that the lane selector 150 selects the data signal Data2_I0 (=0) and outputs as the data signal Data3_f (=0).

When the chip clock signal ChipClock rises at the time t2′, the Data4_r (=1) is fetched by the flip-flop FF2_r. Then, the output data signal OutputData_r of the flip-flop FF2_r is changed to “1”. At the same time, the Data4_f (=0) is fetched by the flip-flop FF2_f, and the output data signal OutputData_f of the flip-flip FF2_f is changed to “0”. Further, when the internal strobe signal Strobe2 rises, the Data3_r (=0) is fetched by the flip-flop FF1_r, and the output data signal Data4_r of the flip-flop FF1_r is changed to “0”. At the same time, the Data3_f (=0) is fetched by the flip-flop FF1_f, and the output data signal Data4_f of the flip-flip FF1_f is changed to “0”. Further, when the internal strobe signal Strobe2 rises and when the counter CT2 switches the select signal lane_sel2 to “1”, the lane selector 150 selects the data signal Data2_I1 (including =1), and outputs as the data signal Data3_r (including =1). At this time, the value of the select signal lane_sel2+1 is “2”, so that the lane selector 150 selects the data signal Data2_I2 (=1) and outputs as the data signal Data3_f (=1).

When the chip clock signal ChipClock rises at the time t3′, the Data4_r (=0) is fetched by the flip-flop FF2_r, and the output data OutputData_r of the flip-flop FF2_r is changed to “0”. At the same time, the Data4_f (=0) is fetched by the flip-flop FF2_f, and the output data signal OutputData_f of the flip-flop FF2_f is changed to “0”. Further, when the internal strobe signal Strobe2 rises, the Data3_r (=1) is fetched by the flip-flop FF1_r. Then, the output data signal Data4_r of the flip-flop FF1_r is changed to “1”. At the same time, the Data3_f (=1) is fetched by the flip-flop FF1_f. Then, the output data signal Data4_f of the flip-flop FF1_f is changed to “1”. Further, when the internal strobe signal sTrobe2 rises and when the counter CT2 switches the select signal lane_sel2 to “0”, the lane selector 150 selects the data signal Data2_I0 and outputs as the data signal Data3_r. At this time, the value of the select signal lane_sel2+1 is “1”, so that the lane selector 150 selects the data signal Data2_I1 and outputs as the data signal Data3_f.

When the chip clock signal ChipClock rises at the time t4′, the Data4_r (=1) is fetched by the flip-flop FF2_r. Then, the output data signal OutputData_r of the flip-flop FF2_r is changed to “1”. At the same time, the Data4_f (=1) is fetched by the flip-flop FF2_f. Then, the output data signal OutputData_f of the flip-flop FF2_f is changed to “1”. Further, when the internal strobe signal Strobe2 rises, the Data3_r (=0) is fetched by the flip-flop FF1_r. Then, the output data signal Data4_r of the flip-flop FF1_r is changed to “0”. At the same time, the Data3_f (=0) is fetched by the flip-flop FF1_f. Then, the output data signal Data4_f of the flip-flop FF1_f is changed to “0”. Further, when the internal strobe signal Strobe2 rises and when the counter CT2 switches the select signal lane_sel2 to “2”, the lane selector 150 selects the data signal Data2_I2 and outputs as the data signal Data3_r. At this time, the value of the select signal lane_sel2+1 is “0”, so that the lane selector 150 selects the data signal Data2_I0 and outputs as the data signal Data3_f.

When the chip clock signal ChipClock rises at the time t5′, the Data4_r (=0) is fetched by the flip-flop FF2_r. Then, the output data signal OutputData_r of the flip-flop FF2_r is changed to “0”. At the same time, the Data4_f (=0) is fetched by the flip-flop FF2_f. Then, the output data signal OutputData_f of the flip-flop FF2_f is changed to “0”.

As described above, the data signal Data input at a double data rate is output as the data signal OutputData_r corresponding to the rising edge of the Strobe1 of double data rate, and also as the data signal OutputData_f corresponding to the falling edge of the Strobe1.

In the present embodiment, similarly to the second and third embodiments, as shown in FIG. 14, even when the timing of the rising and falling edges varies by 1 UI (precisely, a value smaller than 1 UI by Δt (very little time)), it is possible to fetch the data signal Data by the latch unit.

In the present embodiment, similarly to the third embodiment, it takes 2 UI to transfer a certain data signal Data from the timing of the external signal Strobe1 to the timing of the internal strobe signal Strobe 2. Further, similarly to the second and third embodiments, it takes 4 UI to output the data signal Data as OutputData_r and OutputData_f, after the data signal Data is transferred to the timing of the internal strobe signal Strobe 2.

For this reason, the latency, which is the time required for the output of the data signal Data that is input to the sample circuit 300 from the outside to the outside from the sample circuit 300, is 6 UI.

In the third embodiment, one output of the lane selector 50 is taken into the flip-flop FF1_r at the rising edge of the internal strobe signal Strobe2 and is also taken into the flip-flop FF1_f at the falling edge of the internal strobe signal Strobe2. In the present embodiment, one of the outputs of the lane selector 150 is taken into the flip-flop FF1_r at the rising edge of the internal strobe signal Strobe1, and the other output of the lane selector 150 is taken into the flip-flop FF1_f at the rising edge of the internal strobe signal Strobe2. Thus, in the third embodiment, it is necessary to increase the accuracy of the timing of both the rising and falling edges of the internal strobe signal Strobe2, and thus to design the sample circuit in such a way that the duty ratio of the internal strobe signal Strobe2 is close to 50%. However, in the present embodiment, it is only necessary to increase the accuracy of the rising edge of the internal strobe signal Strobe2, so that it is possible to flexibly design the duty ratio of the internal strobe signal Strobe2.

Note that it is assumed that the sample circuit of FIG. 13 includes three lanes. However, the present invention is not limited to this example. The sample circuit may include N lanes.

When the sample circuit includes N lanes, the select signal lane_sel1 is generated by a first N-ary counter. The gate unit includes N gate circuits and the latch unit includes N latch circuits, in which the lane selector selects and outputs two of the outputs of the N latch circuits according to the select signal lane_sel2 output from a second N-ary counter.

More specifically, the first N-ary counter increases the value of the select signal lane_sel1 by “1” in synchronization with the timing of the rising and falling edges of the strobe signal Strobe1.

The gate unit includes first to N selectors. An i-th selector (i=1 to N) outputs a data signal when the value of the select signal lane_sel1 is an i-th value (=i-1). Further, the i-th selector outputs 0 when the value of the select signal lane_sel1 is other than the i-th value.

The latch unit includes first to Nth comparison circuits, as well as first to Nth transmission latches.

An i-th comparison circuit (i=1 to N) compares the value of the select signal lane_sel1 with the i-th value (=i-1). Then, the i-th comparison circuit outputs a high level signal when the two values are the same, and outputs a low level signal when the two values are different.

An i-th transmission latch (i=1 to N) includes a data input terminal for receiving the data signal, as well as an enable terminal for receiving the output signal of the i-th comparison circuit.

The second N-ary counter generates the select signal lane_sel2 that indicates which one of the outputs of the first to N-th transmission latches is selected as the first output, according to the internal strobe signal Strobe2. The second N-ary counter increase the value of the select signal lane_sel2 by “2” in synchronization with the timing of the rising edge of the strobe signal Strobe2.

The lane selector receives the outputs of the first to N the transmission latches. Then, the lane selector outputs one of the outputs of the first to Nth transmission latches, as the first output, based on the value of the select signal lane_sel2. Further, the lane selector outputs one of the outputs of the first to Nth transmission latches, as the second output, based on the value obtained by adding “1” to the value of the select signal lane_sel2.

When the number of lanes is N, the configuration and operation of the flip-flops FF1_r, FF1_f, FF2_r and FF2_f are the same as when the number of lane is two.

Although the invention made by the present inventors has been concretely described based on the embodiments, the present invention is not limited to the exemplary embodiments. It is apparent to those skilled in the art that various modifications and variations can be made without departing from the scope of the present invention.

What is claimed is:

1. A semiconductor device that transmits a data signal input at a double data rate from the outside,
the semiconductor device comprising:
a first selection unit for generating a first selection signal that indicates which one of a plurality of lanes for transmitting the data signal is selected, based on a first strobe signal input from the outside;
a gate unit for sorting the data signal into any of the lanes and outputting data signals based on the first selection signal; and
a latch unit for latching the data signals output to the lanes based on the first selection signal.

2. The semiconductor device according to claim 1,
wherein the lanes are a first lane and a second lane, and
wherein the first selection unit sets the first selection signal to a first level that indicates selecting the first lane, or to a second level that indicates selecting the second lane.

3. The semiconductor device according to claim 2,
wherein the first selection unit includes a binary counter, and
wherein the binary counter changes the level of the first selection signal in synchronization with the timing of the rising and falling edges of the first strobe signal.

4. The semiconductor device according to claim 3;
wherein the gate unit comprises:
a first logic circuit that outputs the logical product of the data signal and the signal obtained by inverting the level of the first selection signal, to the first lane; and
a second logical circuit that outputs the logical product of the data signal and the first selection signal to the second lane.

5. The semiconductor device according to claim 3;
wherein the latch unit comprises:
a first comparison circuit that compares the level of the first selection signal with the first level, and outputs a high level signal when the two levels are the same, while outputting a low level signal when the two levels are different;
a first transmission latch comprising a data input terminal for receiving the data signal, as well as an enable terminal for receiving the output signal of the first comparison circuit;
a second comparison circuit that compares the level of the first selection signal with the second level, and outputs a high level signal when the two levels are the same, while outputting a low level signal when the two levels are different; and
a second transmission latch comprising a data input terminal for receiving the data signal, as well as an enable terminal for receiving the output signal of the second comparison circuit.

6. The semiconductor device according to claim 5, further comprising:
a first flip-flop that holds the output of the first transmission latch in synchronization with the timing of the rising edge of a second strobe signal that is generated based on an internal clock signal; and
a second flip-flop that holds the output of the second transmission latch in synchronization with the timing of the falling edge of the second strobe signal.

7. The semiconductor device according to claim 1,
wherein the lanes are first to Nth lanes,
wherein the first selection unit sets the first selection signal to any one of the first to Nth values, each of which indicates a selection of the first to Nth lanes, according to the first strobe signal.

8. The semiconductor device according to claim 7,
wherein the first selection unit includes a first N-ary counter, and
wherein the first N-ary counter increases the value of the first selection signal by “1” in synchronization with the timing of the rising and falling edges of the first strobe signal.

9. The semiconductor device according to claim 8,
wherein the gate unit includes first to Nth selectors,
wherein an i-th selector outputs the data signal when the value of the first selection signal is an i-th value, and outputs 0 when the value of the first selection signal is other than the i-th value, in which i is any value in the range of 1 to N.

10. The semiconductor device according to claim 8,
wherein the latch unit includes:
first to Nth comparison circuits; and
first to Nth transmission latches,
wherein an i-th comparison circuit compares the value of the first selection signal with the i-th value, and outputs a high level signal when the two values are the same, while outputting a low level signal when the two values are different, and
wherein an i-th transmission latch comprises a data input terminal for receiving the data signal, as well as an enable terminal for receiving the output signal of the i-th comparison circuit.

11. The semiconductor device according to claim 10, further comprising:
a second selection unit that generates a second selection signal that indicates which one of the outputs of the first to Nth transmission latches is selected, according to a second strobe signal that is generated based on an internal clock signal; and
a lane selector that receives outputs of the first to N transmission latches, and outputs one of the outputs of the first to Nth transmission latches based on the value of the second selection signal,
wherein the second selection unit includes a second N-ary counter, and
wherein the second N-ary counter increases the value of the second selection signal by “1” in synchronization with the timing of the rising and falling edges of the second strobe signal.

12. The semiconductor device according to claim 11, further comprising:
a first flip-flop that holds the output of the lane selector in synchronization with the timing of the rising edge of the second strobe signal; and
a second flip-flop that holds the output of the lane selector in synchronization with the timing of the falling edge of the second strobe signal.

13. The semiconductor device according to claim 10, further comprising:
a second selection unit that generates a second selection signal that indicates which one of the outputs of the first to Nth transmission latches is selected, according to a second strobe signal that is generated based on an internal clock signal; and
a lane selector that receives outputs of the first to Nth transmission latches, and outputs two of the outputs of the first to Nth transmission latches, based on the value of the second selection signal as well as the value obtained by increasing the value of the second selection signal by “1”,
wherein the second selection unit includes a second N-ary counter, and
wherein the second N-ary counter increases the value of the second selection signal by “2” in synchronization with the timing of the rising edge of the second strobe signal.

14. The semiconductor device according to claim 13, further comprising:
a first flip-flop that holds a first output of the lane selector in synchronization with the timing of the rising edge of the second strobe signal; and
a second flip-flop that holds a second output of the lane selector in synchronization with the timing of the rising edge of the second strobe signal.

15. The semiconductor device according to claim 6, further comprising:
a third flip-flop that holds the output of the first flip-flop in synchronization with the timing of the rising edge of the internal clock signal; and
a fourth flip-flop that holds the output of the second flip-flop in synchronization with the timing of the rising edge of the internal clock signal.

16. A semiconductor device comprising:
a circuit that, based on a first strobe signal input from the outside, detects a data signal input from the outside by level sensitive operation and holds the input data signal; and
a flip-flop that fetches the output of the latch based on a second strobe signal synchronized with a clock signal inside the chip.
